(19) United States
(12) Patent Application Publication
(10) Pub. No.: US 2007/0029648 A1
(43) Pub. Date: Feb. 8, 2007

(54) Enhanced multi-die package

(75) Inventors: Mark Allen Gerber, Plano, TX (US); John Edwin Moltz JR., McKinney, TX (US)

Correspondence Address: TEXAS INSTRUMENTS INCORPORATED, P O BOX 655474, M/S 3999, DALLAS, TX, 75265, US

(73) Assignee: Texas Instruments Incorporated

(21) Appl. No.: 11/194,972

(22) Filed: Aug. 2, 2005

(51) Int. Cl. H01L 23/495

(52) U.S. Cl. 257/666

(57) ABSTRACT

System and method for a thermal and space efficient integrated circuit package. A preferred embodiment comprises a first lead frame with a first surface to which a first die is attached and a second surface external to a multi-die package, a second lead frame with a first surface to which a second die is attached, wherein the first die and the second die are arranged so that they face each other. The present invention further comprises a first plurality of pins arranged around the first lead frame and a second plurality of pins arranged around the second lead frame. Finally, a package body encapsulates the first lead frame and the second lead frame with a portion of each pin in the first plurality of pins and the second plurality of pins extending outside the package body.

### TECHNICAL FIELD

The present invention relates generally to a system and method for integrated circuits, and more particularly to a system and method for a thermal and space efficient integrated circuit package.

### BACKGROUND

It is a common desire to increase the functionality of a packaged integrated circuit without increasing the package's physical size, mainly the footprint of the package, since a package with an increased footprint may require the redesign of a product in which it is used to accommodate the larger package size. In some applications, an increase in the footprint of a package may preclude its use.

One technique used to increase functionality without increasing the package footprint is to decrease the feature size of the devices in the integrated circuit contained in the package by using a more advanced fabrication process to create the integrated circuit contained in the package. By decreasing the feature size, more devices can be integrated onto an integrated circuit die while keeping the size of the integrated circuit die constant.

Another technique that can be used to increase functionality is to place more than one integrated circuit die into a single package. Functionality can then be increased with a relatively small increase in cost and package complexity. The multiple integrated circuit die can be arranged into a die stack or bonded onto different sides of a die bond pad, for example. The multiple integrated circuit die may be connected to one another electrically or they may operate independently of one another. Each integrated circuit die may be coupled to its own set of input/output pins.

One disadvantage of the prior art is that the use of an advanced fabrication process to increase integration can be expensive, thereby increasing the cost of the packaged product. The increased cost may have to be either absorbed by the manufacturer or passed onto customers.

A second disadvantage of the prior art is that the arranging of integrated circuit die into a die stack structure or bonding the die onto different sides of a die bond pad can limit the ability to remove heat generated by the die. This can put a limit on the types of integrated circuit applications that can make use of the packaging. For example, high-heat products, such as general purpose and special purpose processors, are unlikely candidates due to their high heat dissipation requirements.

Yet another disadvantage of the prior art is that there is a need to use complex lead frame designs when integrated circuit dies are attached to both surfaces of a single die bond pad, which can lead to increased manufacturing costs. Furthermore, the need to attach integrated circuit dies to both surfaces of a single die bond pad can complicate the packaging of the integrated circuit dies, potentially decreasing yield and increasing costs.

### SUMMARY OF THE INVENTION

These and other problems are generally solved or circumvented, and technical advantages are generally achieved, by preferred embodiments of the present invention which provides a system and method for a thermal and space efficient integrated circuit package.

In accordance with a preferred embodiment of the present invention, a multi-die package is provided. The multi-die package includes a first lead frame with a first surface to which a first die is attached and a second surface external to the multi-die package, and a second lead frame with a first surface to which a second die is attached. The first surface of the first lead frame and the first surface of the second lead frame are arranged so that they are facing each other, with the first lead frame and the second lead frame fixed together. The multi-die package also includes a plurality of pins arranged around the first lead frame and the second lead frame, wherein a number of pins are electrically coupled to the first lead frame and a remainder of the pins are coupled to the second lead frame. The multi-die package includes a package body that encapsulates the first lead frame and the second lead frame, with a portion of each pin extending outside of the package body.

In accordance with another preferred embodiment of the present invention, a method for packaging multiple dies in a single package is provided. The method includes attaching a first die to a first lead frame, attaching a second die to a second lead frame, arranging the first lead frame and the second lead frame so that the first die and the second die are facing each other, and fixing the first lead frame to the second lead frame. The method also includes forming a package body around the first lead frame and the second lead frame.

In accordance with another preferred embodiment of the present invention, a multi-die package is provided. The multi-die package includes a first lead frame for the attachment of one or more die, and a second lead frame for the attachment of one or more die, wherein the second lead frame is inverted and the die attached to the second lead frame is facing the die attached to the first lead frame. The multi-die package also includes a first plurality of pins electrically coupled to pads on the die attached to the first lead frame and a second plurality of pins electrically coupled to pads on the die attached to the second lead frame. The multi-die package further includes a package body that encapsulates the first lead frame, the second lead frame, and a portion of pins in the first plurality of pins and the second plurality of pins, with a surface of the first lead frame not being encapsulated by the package body.

An advantage of a preferred embodiment of the present invention is that multiple integrated circuit dies can be placed into a single package, with each die being provided good heat dissipation properties. This will enable the ability to place multiple high heat dissipation dies into a single package.

A further advantage of a preferred embodiment of the present invention is that it makes use of a plurality of simple and low-cost lead frames rather than a single complex and high-cost lead frame. This can simplify the manufacturing process as well as help keep the cost of the package low.

Yet another advantage of a preferred embodiment of the present invention is that it is possible to stack multiple packages vertically to further increase the functionality while at the same time keeping the package's overall footprint constant. Furthermore, given equivalent functionality, testing of a stack of multiple packages can be simpler than testing a single package, since each package in the stack can be tested individually (with less functionality per package) while the single package must be tested in its entirety.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and specific embodiments disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1a and 1b are diagrams of cross sectional views of prior art packaged integrated circuits with multiple dies;

FIGS. 2a and 2b are diagrams of cross sectional views of packaged integrated circuits with multiple dies, according to a preferred embodiment of the present invention;

FIGS. 3a through 3c are diagrams of top views of lead frames used in the packaging of multiple dies in a single integrated circuit package as well as a lead frame alignment feature of the lead frames, according to a preferred embodiment of the present invention;

FIGS. 4a through 4e are diagrams of cross sectional views of packaged integrated circuits with multiple dies, according to a preferred embodiment of the present invention; and

FIG. 5 is a diagram of a sequence of events in the manufacture of a multi-die package, according to a preferred embodiment of the present invention.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The present invention will be described with respect to preferred embodiments in a specific context, namely a multi-die package for use in size critical applications, such as in consumer electronics. The invention may also be applied, however, to other applications wherein a high degree of functionality is desired as well as low cost, high heat dissipation, ease of testability, ease of design, and so forth are desired, such as in size critical applications, low cost applications, performance critical applications, and so on.

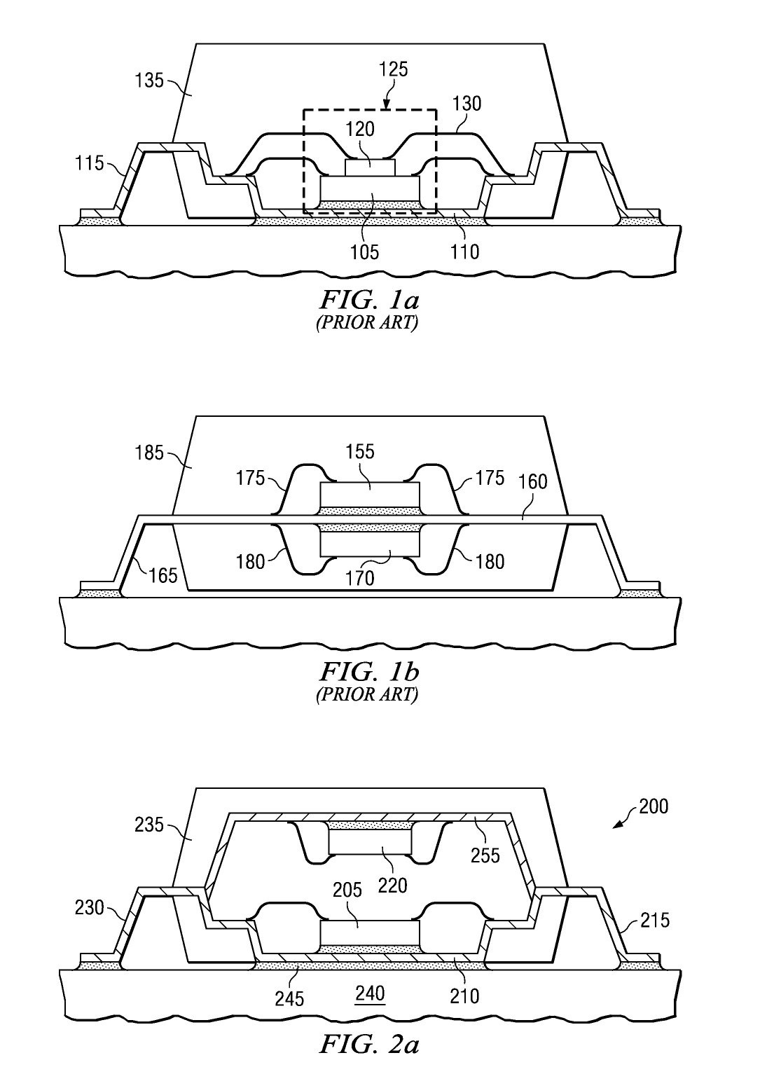

With reference now to FIGS. 1a and 1b, there are shown diagrams illustrating cross sectional views of packaged integrated circuits made using prior art techniques for increasing functionality of a packaged integrated circuit by placing more than one integrated circuit die into a single package. A prior art technique of stacking integrated circuit die is shown in FIG. 1a. The technique involves placing a first integrated circuit die 105 onto a die bond pad 110 of a lead frame 115 and then placing a second integrated circuit die 120 on top of the first integrated circuit die 105. The structure can be referred to as a die stack 125. If additional dies are to be included in the package, the additional dies can be added to the die stack 125. The dies in the die stack can share electrical signals with the use of solder pads and solder bumps (not shown), for example. However, there is no requirement that the dies be able to communicate to one another. The dies can be coupled to pins in the lead frame 115 to permit connectivity with components external to the package with the use of bond wires 130 that couple input/output pads on the dies to the pins of the package. Once the bond wires 130 have been placed, the lead frame containing the die stack can be placed into a mold and the remainder of the package, such as a package body 135, can be formed.

Another prior art technique for placing more than one integrated circuit die into a single package is shown in FIG. 1b. The technique involves attaching a first integrated circuit die 155 onto a first surface of a die bond pad 160 of a lead frame 165 and then attaching a second integrated circuit die 170 onto a second (and opposing) surface of the same die bond pad 160. The first integrated circuit die 155 can be coupled to pins in the lead frame 165 via bond wires 175, while the second integrated circuit die 170 can be coupled to pins in the lead frame 165 via bond wires 180. Should additional dies be included in the package, die stacks can be formed on either the first integrated circuit die 155 or the second integrated circuit die 170. The lead frame 165 with the attached integrated circuit dies can then be placed into a mold and the remainder of the package, such as a package body 185, can be formed.

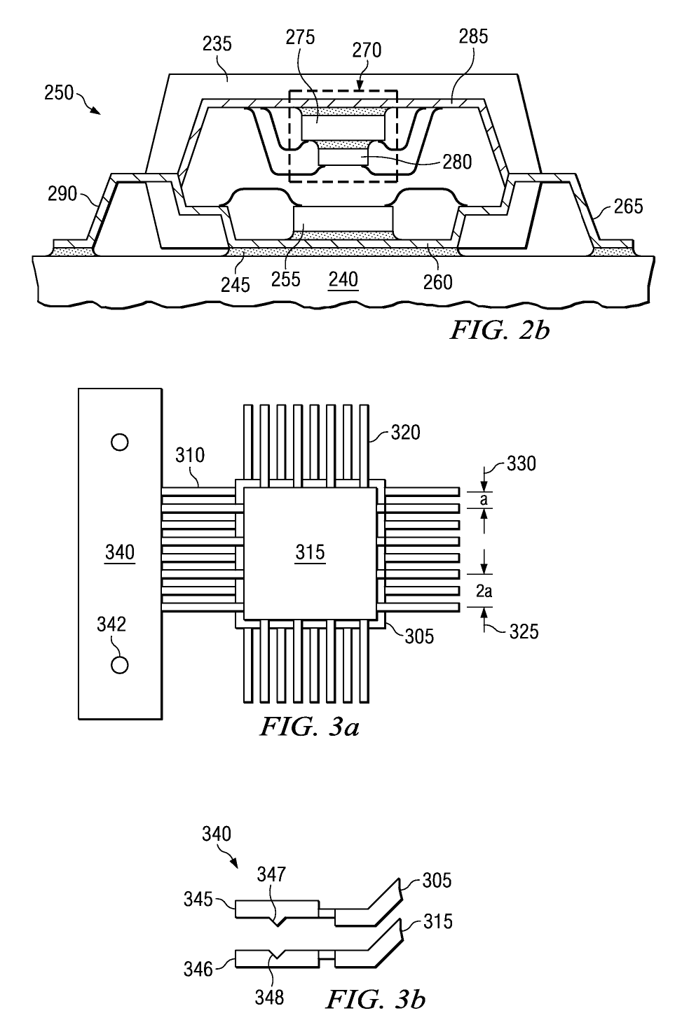

With reference now to FIGS. 2a and 2b, there are shown diagrams illustrating a cross sectional view of a packaged integrated circuit 200 and 250 containing multiple integrated circuit dies, according to a preferred embodiment of the present invention. As shown in FIG. 2a, a first integrated circuit die 205 can be attached to a first die bond pad 210 of a first lead frame 215 and a second integrated circuit die 220 can be attached to a second die bond pad 225 of a second lead frame 230. It is difficult to see in a cross sectional view, but the first lead frame 215 and the second lead frame 230 can be electrically separate entities. The first lead frame 215 and the second lead frame 230 can be fixed into a single unit, for example, with the use of glue, and then placed into a mold and the remainder of the packaged integrated circuit 200, such as a package body 235, can be formed. Once the packaged integrated circuit 200 is complete, it can be attached to a substrate (or a circuit board) 240 with solder. The first die bond pad 210, used to attach the first integrated circuit die 205 may have a surface external to the package body 235 and can also be attached to the substrate 240 with solder (or some thermally conductive material) 245 to help dissipate heat produced by the first integrated circuit die 205.

With reference now to FIG. 2b, a cross sectional view of a packaged integrated circuit 250 with three integrated circuit dies is provided. The packaged integrated circuit 250 contains a first integrated circuit die 255 can be attached to a first die bond pad 260 of a first lead frame 265 and a die stack 270, comprising a second integrated circuit die 275 and a third integrated circuit die 280, can be attached to a second die bond pad 285 of a second lead frame 290. The use of die stacks can permit the inclusion of more than two integrated circuit dies in a single integrated circuit package. According to a preferred embodiment of the present invention, die stacks can be attached to both the first die bond pad 260 and the second die bond pad 285, therefore, more than three integrated circuit dies can be included in a single integrated circuit package. There may not be an actual limit to the number of integrated circuit dies that can be placed in a single integrated circuit package. However, factors such as a maximum number of input/output pins available for use, a maximum height of the integrated circuit package, testability, and so forth, may place a practical limit on the number of integrated circuit dies in a single integrated circuit package.

The use of separate lead frames to mount the first integrated circuit die 205 and the second integrated circuit die 220 can allow for separate mounting of the integrated circuit dies to their respective lead frames. This can permit the attachment to occur on different manufacturing lines and then the lead frames can be joined immediately prior to the completion of the integrated circuit package. Therefore, existing die attachment technologies can be used to attach the integrated circuit die to the lead frames and will preclude the need to develop new die attachment technologies that will permit operations such as attaching the integrated circuit dies to both sides of a die attachment pad. This can help reduce the manufacturing costs involved in the packaging of the integrated circuit dies.

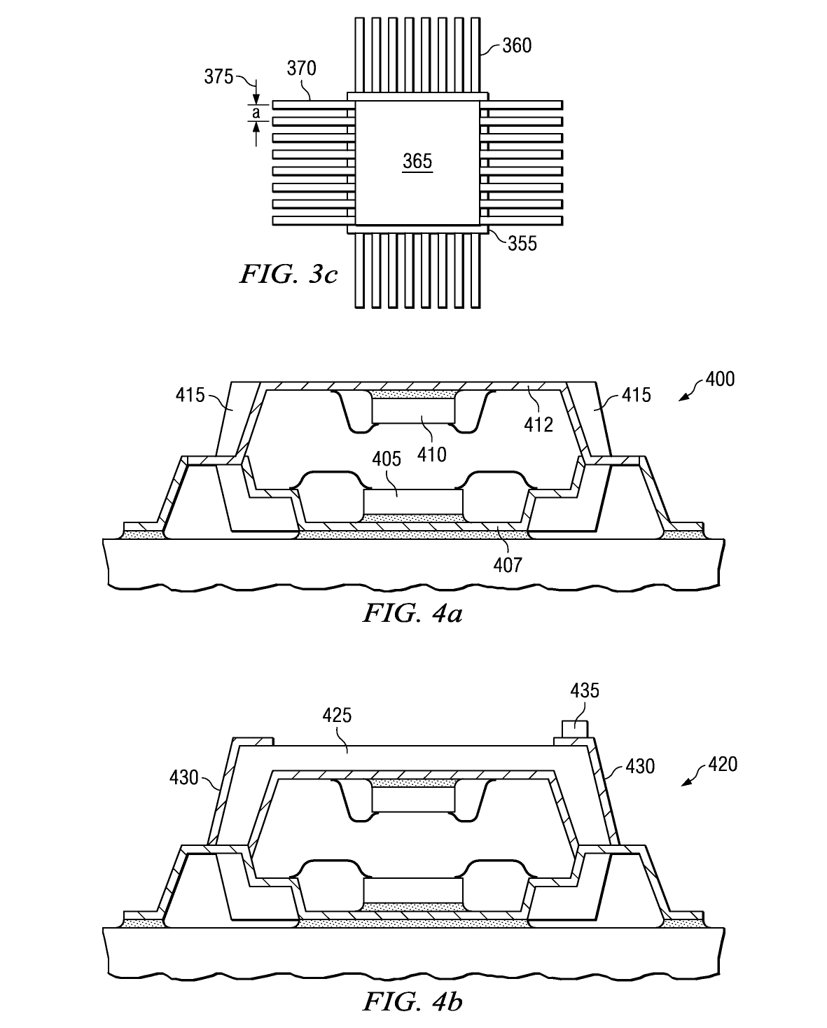

With reference now to FIGS. 3a through 3c, there are shown diagrams illustrating top views of lead frames used in the packaging of multiple integrated circuit dies in a single integrated circuit package, according to a preferred embodiment of the present invention. The diagrams shown in FIGS. 3a and 3c illustrate top views of exemplary lead frames for use in the packaging of multiple integrated circuit dies in a single integrated circuit package, while FIG. 3b illustrates a side view of a lead frame alignment feature of the lead frames. Other variations of arrangement of the lead frames are possible and are not precluded by the exemplary lead frames illustrated herein.

With reference to FIG. 3a, there is illustrated a top view of a first lead frame 305 with a plurality of pins, such as pin 310, and a second lead frame 315 with a plurality of pins, such as pin 320. As shown in FIG. 3a, the view illustrates a top surface of the first lead frame 305 and a bottom surface of the second lead frame 315. According to a preferred embodiment of the present invention, the pins 310 of the first lead frame 305 are interleaved with the pins 320 of the second lead frame 315. Inter-pin spacing between pins in a single lead frame can be ‘2a’ apart (shown as interval 325) and inter-pin spacing between pins of both lead frames can be ‘a’ apart (shown as interval 330). The interleaving of the pins can permit electrical connections to be made to any of the four sides of the packaged integrated circuit.

Each of the two lead frames (the first lead frame 305 and the second lead frame 315) can have a lead frame alignment fixture 340. The lead frame alignment feature 340 can be used to help ensure that the two lead frames are maintained in proper alignment while they are being fixed together or while being placed in a mold. The lead frame alignment feature 340 can have a plurality of alignment holes, such as alignment hole 342 to help properly register the part of the lead frame alignment feature 340 attached to the first lead frame 305 to the part of the lead frame alignment feature 340 attached to the second lead frame 315. The alignment holes may be designed so that as the two parts of the lead frame alignment feature 340 are brought together, the two parts automatically align. Although referred to as holes, the alignment holes may actually be a hole (or indentation) on a lead frame alignment feature of one lead frame and a pin or nipple on a lead frame alignment feature of another lead frame.

With reference to FIG. 3b, there is illustrated a side view of the lead frame alignment feature 340. Shown are the two parts of the lead frame alignment feature 340, a first part 345 and a second part 346. Also shown is an alignment hole, comprising a male portion 347 and a female portion 348. Attached to the first part 345 is the first lead frame 305 (shown in part) and attached to the second part 346 is the second lead frame 315 (shown in part).

With reference to FIG. 3c, there is illustrated a top view of a first lead frame 355 with a plurality of pins, such as pin 360, and a second lead frame 365 with a plurality of pins 370. The lead frames shown in FIG. 3c differ from the lead frames shown in FIG. 3a in that the lead frames have pins arranged along certain sides rather than all four sides. Since there is no interleaving between pins of the two lead frames, the pins of a single lead frame can have an inter-pin spacing of ‘a’ (shown as interval 375). Although shown as having pins on opposite sides, various implementations may have adjacent sides having pins. Also, one lead frame may have pins on three sides while another lead frame may have pins on one side. FIG. 3c does not illustrate a lead frame alignment feature, but the first lead frame 355 and the second lead frame 365 may provide such a feature.

Many variations on the arrangement and layout of pins for the lead frames are possible. Variations on the arrangement and layout may be dependant upon factors such as the wire routing requirements of the board and circuitry to which the packaged integrated circuit will be attached, availability of lead frames, and so forth.

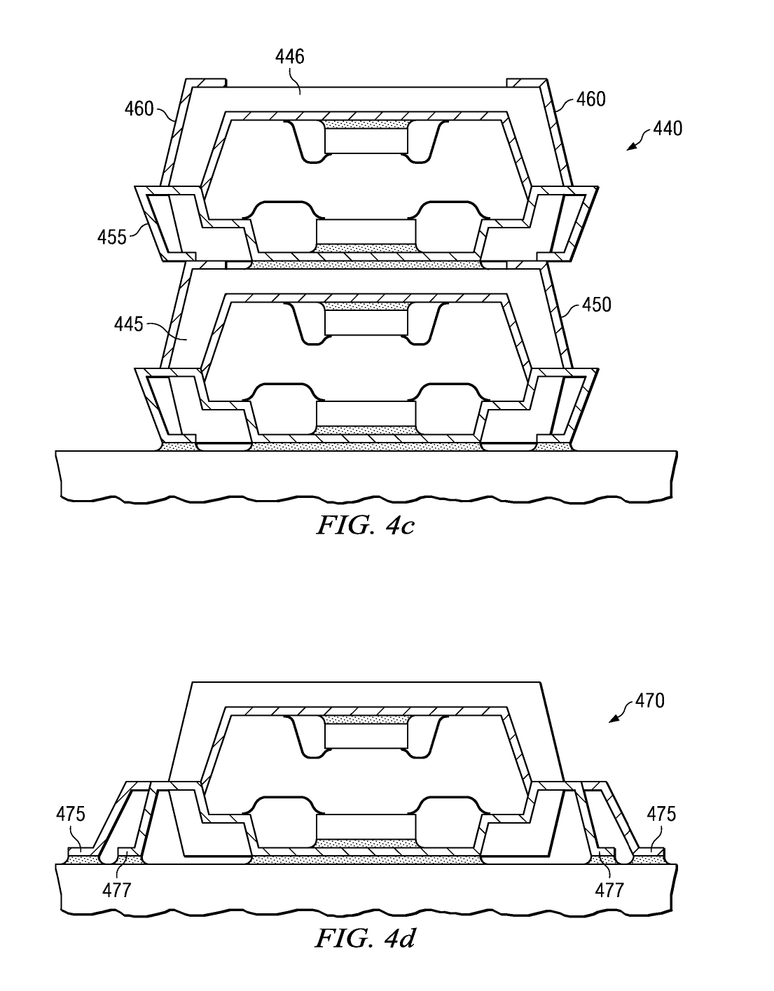

With reference now to FIGS. 4a through 4e, there are shown diagrams illustrating cross sectional views of packaged integrated circuits with multiple integrated circuit dies, according to a preferred embodiment of the present invention. FIGS. 4a through 4e illustrate several embodiments from a wide variety of embodiments of the present invention and should not be construed as being limiting to the present invention.

As discussed previously, heat dissipation can be a problem in packaged integrated circuits with multiple integrated circuit dies. Typically, the material used to form the package body does not have good heat conductivity properties. Therefore, it may not be possible to safely place integrated circuit dies that require significant heat dissipation. FIG. 4a illustrates a multi-die package 400 with a first integrated circuit die 405 attached to a first die bond pad 407 and a second integrated circuit 410 attached to a second die bond pad 412. Both the first die bond pad 407 and the second die bond pad 412 have a surface (a bottom surface opposite a surface to which the integrated circuit dies are attached) that lies external to a package body 415 once the multi-die package 400 is complete. The bottom surfaces of the first die bond pad 407 and the second die bond pad 412 can permit the attachment of heat dissipation devices that help improve the heat dissipation properties of the multi-die package 400. For example, the bottom surface of the first die bond pad 407 can be attached to a substrate or a printed circuit board to help dissipate heat and the bottom surface of the second die bond pad 412 (a top surface of the multi-die package 400) can be attached to a heat sink to help dissipate heat. Since the integrated circuit dies have good thermal conductive properties, a die stack (referencing the die stack 270 (FIG. 2b)) attached to either (or both) die bond pad can have good heat dissipation for all integrated circuit dies in the die stack.

Another situation that may arise involves a desire to include connectors for use as test points, connection of discrete components (such as capacitors, resistors, inductors), permitting vertical stacking of packaged integrated circuits, and so forth. By placing the connectors on a top surface of a multi-die package, a reduction in required surface area on a circuit board can be achieved. For example, rather than using space on the circuit board for test points, discreet components, or other packaged integrated circuits, they can be placed on top of a packaged integrated circuit already on the circuit board thereby freeing the surface area for other use or for reducing an overall size of the circuit board. FIG. 4b illustrates a multi-die package 420 with connectors, such as connector 430, formed on a top surface of a package body 425. The connector can be used as a test point, permit the attachment of discrete components (such as component 435), other packaged integrated circuits, or so on. According to a preferred embodiment of the present invention, the connector 430 can be a preformed component of a lead frame, specifically designed to have a portion lying external to the package body 425 once the package body 425 is completed. Alternatively, the connector 430 may have an appearance of a normal pin that can be bent into position once the package body 425 is completed.

With reference to FIG. 4c, the diagram illustrates a vertical package stack 440 comprising two packaged integrated circuits, a bottom package 445 and a top package 446. One, both, or none of the packaged integrated circuits may contain two or more integrated circuit dies. The bottom package 445 features connectors, such as connector 450 formed on a top surface of the bottom package 445 to permit electrical connectivity with the top package 446. Pins, such as pin 455, on a bottom surface of the top package 446 can couple with the connectors 450. The top package 446 may also feature connectors, such as connector 460, to permit the attachment of additional packaged integrated circuits or discrete components, for use as test points, and so on.

With reference to FIG. 4d, the diagram illustrates a multi-die package 470 with multiple rows of pins. The multi-die package 470 has pins arranged in two rows, a first row 475 and a second row 477. The use of multiple rows can allow increased pin-to-pin spacing. The increased spacing between pins can prevent short circuits from forming and can improve routability for signals on the substrate the multi-die package 470 is attached to. In FIG. 4e, the diagram illustrates a multi-die package 480 with multiple rows of pins and with connectors, such connector 485, on a top surface of the multi-die package 480 to permit the coupling of test probes, discrete components (such as component 487), other packaged integrated circuits, and so on.

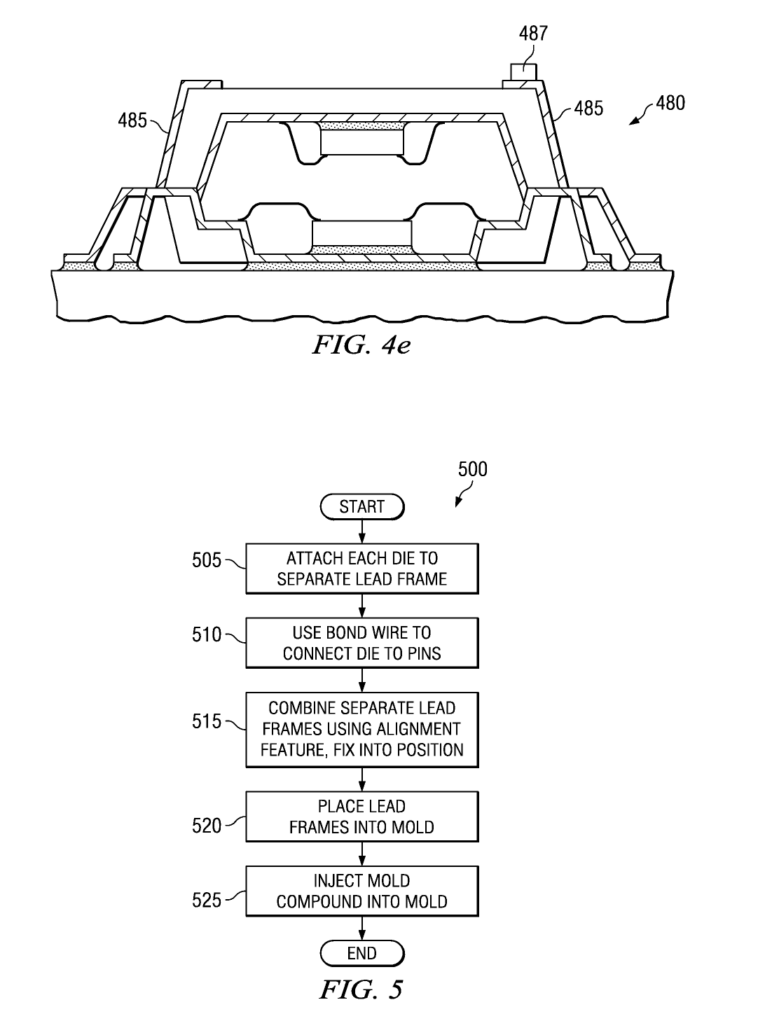

With reference now to FIG. 5, there is shown a flow diagram illustrating a sequence of events in the manufacture of a multi-die package, according to a preferred embodiment of the present invention. As discussed previously, the manufacture of the multi-die package can be performed using existing manufacturing equipment without significant investment in retooling or developing new equipment. The manufacture of the multi-die package can begin by attaching an integrated circuit die to one of two lead frames (block 505). If there are more than two integrated circuit dies to be included in the multi-die package, then a multi-die die stack can be formed on one or both of the lead frames. The attachment of the integrated circuit die to the lead frame can be performed separately in different manufacturing steps. Therefore, standard attachment equipment, materials, and processes can be used. Once the integrated circuit die(dies) are attached to the lead frame, bond wires can be used to electrically couple input/output pins on the lead frame to pads on the integrated circuit die (block 510). Again, standard bonding equipment can be used in place of specially designed bonding equipment which may be required if special lead frames were created to support the use of multiple integrated circuit dies. The attachment and bonding of integrated circuit die to lead frames in separate operations can permit the operations to take place in different manufacturing lines or manufacturing facilities and at different times. The attachment and bonding operations can take place at a time prior to the manufacture of the multi-die package and then stored for subsequent use.

After attaching and bonding, the two lead frames can be combined and fixed into position (block 515). According to a preferred embodiment of the present invention, the two lead frames can be fixed into a desired position with glue or solder. The lead frame alignment feature (FIGS. 3a and 3b) can be used to help ensure proper alignment. A first lead frame will become a bottom lead frame and a second lead frame will become a top lead frame. The selection of the bottom lead frame may be based on considerations such as heat dissipation requirements, die size, and so forth. For example, if the top lead frame cannot have an exposed bottom surface due to restrictions such as a requirement to place discrete components on the multi-die package, then the bottom lead frame will likely be attached to an integrated circuit die requiring the greatest heat dissipation. With the lead frames fixed together (block 515), the lead frames can be placed in a mold (block 520) and mold compound can be injected into the mold to form a package body (block 525). Once the mold compound cures, the multi-die package can be taken out of the mold and may receive additional processing to complete the packaging, such as singulation, placement of discrete components, and so forth.

Although the present invention and its advantages have been described in detail, it should be understood that various changes, substitutions and alterations can be made herein without departing from the spirit and scope of the invention as defined by the appended claims.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A multi-die package comprising:
a first lead frame having a first surface to which a first die is attached;
a second lead frame having a first surface to which a second die is attached, wherein the first surface of the first lead frame and the first surface of the second lead frame are arranged so that they are facing each other, wherein the first lead frame is fixed to the second lead frame;
a plurality of pins arranged around the first lead frame and the second lead frame, wherein a number of the pins are electrically coupled to the first lead frame and a remainder of the pins are electrically coupled to the second lead frame; and
a package body encapsulating the first lead frame and the second lead frame, wherein a portion of each pin in the plurality of pins extend outside of the package body and the first lead frame having a second surface external to the package body.

2. The multi-die package of claim 1, wherein the first die or the second die comprises a plurality of dies arranged in a die stack.

3. The multi-die package of claim 1, wherein the second lead frame has a second surface external to the package body.

4. The multi-die package of claim 1, wherein a subset of the plurality of pins are folded over a top surface of the package body.

5. The multi-die package of claim 4, wherein the subset of the plurality of pins are used as one or more of the following: test point connections, discrete component connections, or connections for an integrated circuit package placed on top of the multi-die package.

6. The multi-die package of claim 5, wherein a plurality of integrated circuit packages are placed on top of the multi-die package, wherein the plurality of integrated circuit packages are arranged in a vertical stack.

7. The multi-die package of claim 1, wherein the plurality of pins are arranged in multiple rows.

8. The multi-die package of claim 7, wherein a subset of the plurality of pins are folded over a top surface of the package body.

9. The multi-die package of claim 1, wherein pins electrically coupled to the first lead frame are interleaved with pins electrically coupled to the second lead frame.

10. The multi-die package of claim 1, wherein the second surface of the first lead frame is attached to a circuit board, a substrate, or a heat sink.

11. The multi-die package of claim 1, wherein the dies in the multi-die package are functionally disjoint with respect to one another.

12. A method for packaging multiple dies in a single package, the method comprising:
attaching a first die to a first lead frame;
attaching a second die to a second lead frame;
arranging the first lead frame and the second lead frame so that the first die and the second die are facing each other;
fixing the first lead frame to the second lead frame; and
forming a package body around the first lead frame and the second lead frame.

13. The method of claim 12 further comprising electrically coupling the first die to pins in the first lead frame and the second die to pins in the second lead frame.

14. The method of claim 13, wherein the electrical coupling comprises using bond wire to couple pads on each die to the pins.

15. The method of claim 12, wherein the first attaching or the second attaching is repeated for an additional die or dies.

16. The method of claim 12, wherein the forming comprises:
placing the first lead frame and the second lead frame into a mold; and
injecting a mold compound into the mold.

17. The method of claim 12, wherein a first plurality of pins are coupled to the first lead frame and a second plurality of pins are coupled to the second lead frame, the method further comprising after the forming, bending a subset of pins over a top surface of the package body.

18. The method of claim 17, wherein the subset of pins comprises pins from the first plurality of pins or the second plurality of pins.

19. The method of claim 12, wherein the arranging makes use of a lead frame alignment feature to ensure that the first lead frame and the second lead frame are properly aligned.

20. A multi-die package comprising:
a first lead frame for attachment of one or more die;
a second lead frame for attachment of one or more die, wherein the second lead frame is inverted and the die attached to the second lead frame is facing the die attached to the first lead frame;
a first plurality of pins electrically coupled to pads on the die attached to the first lead frame;
a second plurality of pins electrically coupled to pads on the die attached to the second lead frame; and
a package body encapsulating the first lead frame, the second lead frame, a portion of the pins in the first plurality of pins, a portion of the pins in the second plurality of pins, and wherein a surface of the first lead frame is not encapsulated by the package body.

21. The multi-die package of claim 20, wherein a number of the pins in the first plurality of pins or a number of pins in the second plurality of pins are folded over a top surface of the package body.

22. The multi-die package of claim 20, wherein a surface of the second lead frame is not encapsulated by the package body.
